(19) United States
(12) Patent Application Publication
(10) Pub. No.: US 2023/0106167 A1
(43) Pub. Date: Apr. 6, 2023

(54) DE-BONDING OF THICK FILMS FROM CARRIER AND METHODS THEREOF

(71) Applicant: ARIZONA BOARD OF REGENTS ON BEHALF OF ARIZONA STATE UNIVERSITY, Scottsdale, AZ (US)

(72) Inventors: Nicholas MUNIZZA, Gilbert, AZ (US); Michael MARRS, Phoenix, AZ (US); Xan HENDERSON, Mesa, AZ (US)

(73) Assignee: ARIZONA BOARD OF REGENTS ON BEHALF OF ARIZONA STATE UNIVERSITY, Scottsdale, AZ (US)

(21) Appl. No.: 17/938,175

(22) Filed: Oct. 5, 2022

Related U.S. Application Data
(60) Provisional application No. 63/252,413, filed on Oct. 5, 2021.

(51) Int. Cl. H01L 27/12; H01L 21/683

(52) U.S. Cl. CPC H01L 27/1266; H01L 21/6835; H01L 27/1218; H01L 2221/68386

(57) ABSTRACT

A method for coating a multi-layered polymer film is disclosed including coating a first layer of polyimide onto a carrier, curing the first layer of polyimide by subjecting the first layer of polyimide to an elevated temperature, depositing a first layer of metal onto the cured first layer of polyimide, coating a second layer of polyimide onto the first layer of metal, and curing the second layer of polyimide by subjecting the second layer of polyimide to an elevated temperature. A flexible electronic device is also disclosed, including multiple interposed layers of polyimide and layers of metal, a dielectric barrier layer disposed on the top layer of polyimide, and a thin film transistor-based device disposed on the dielectric barrier layer. The flexible electronic device has little to no curl.

### TECHNICAL FIELD

The present teachings relate generally to polymeric substrates for flexible electronics and, more particularly, to the fabrication of thick film polyimide substrates and methods for fabrication of same.

### CROSS REFERENCE TO RELATED APPLICATIONS

This application claims the benefit of U.S. Provisional Pat. Application No. 63/252,413, filed on Oct. 5, 2021, which is hereby incorporated by reference in its entirety.

### BACKGROUND

Flexible polyimide substrate processing techniques are well-known as applied to fabrication of flexible substrates for electronics and electronics products, among other uses. Common polyimide processes utilize laser ablation through glass carriers to release polyimide substrates from the carriers. Upon de-bonding, polyimide films at a thickness of less than approximately 30 microns is difficult to handle without creasing or bending the substrate which is also catastrophic to the deposited thin films. As the polyimide substrate thickness increases, internal mechanical stresses can result in a noticeable curl, which also renders the polyimide quite difficult to handle.

A method and process amendable to a manual de-bond for flexible polyimide substrates having a low adhesion strength to the carrier to enable a laser-free debond while maintaining the required film adhesion necessary to successfully fabricate thin film transistors would provide polyimide and other polymeric substrate materials at lower cost and improved yields. Such a low curl, flexible, polyimide substrate would be useful to a variety of flexible electronics applications such as flexible displays, x-ray detectors, interposers for stacking of electrical components, and medical diagnostic equipment, among many others.

Thus, a method of providing a flexible polyimide substrate backing for flexible electronic devices which can be mechanically delaminated from its carrier substrate, possesses virtually no curl, is easy to handle, and is thick enough to resist wrinkling would be desirable.

### SUMMARY

The following presents a simplified summary in order to provide a basic understanding of some aspects of one or more embodiments of the present teachings. This summary is not an extensive overview, nor is it intended to identify key or critical elements of the present teachings, nor to delineate the scope of the disclosure. Rather, its primary purpose is merely to present one or more concepts in simplified form as a prelude to the detailed description presented later.

A method for coating a multi-layered polymer film is disclosed. The method includes coating a first layer of polyimide onto a carrier, curing the first layer of polyimide by subjecting the first layer of polyimide to an elevated temperature, depositing a first layer of metal onto the cured first layer of polyimide, coating a second layer of polyimide onto the first layer of metal, and curing the second layer of polyimide by subjecting the second layer of polyimide to an elevated temperature.

Exemplary implementations may include releasing the multi-layered polymer film from the carrier without the use of laser ablation. The resulting multi-layered polymer film has little to no curl. The method for coating a multi-layered polymer film may further include depositing a second layer of metal onto the cured second layer of polyimide, coating a third layer of polyimide onto the second layer of metal, and curing the third layer of polyimide by subjecting the third layer of polyimide to an elevated temperature. The carriers used in the method for coating a multi-layered polymer film may include silicon or glass. The first layer of polyimide and the second layer of polyimide produced using the method for coating a multi-layered polymer film are each from about 10 microns to about 20 microns thick. The metal may include molybdenum. The first layer of metal is from about 100 nanometers to about 200 nanometers thick. The method for coating a multi-layered polymer film may include depositing a dielectric barrier layer onto the second layer of polyimide and fabricating a thin film transistor-based device onto the dielectric barrier layer. The dielectric barrier layer may include silicon nitride. The method for coating a multi-layered polymer film may include subjecting the first layer of polyimide to an elevated temperature which may include a temperature of at least 340° C. for 1 hour. The first layer of metal may be deposited in a pattern that does not cover an entire surface of the first layer of polyimide.

A method for fabricating a multi-layered flexible electronic device is also disclosed. The method for fabricating a multi-layered flexible electronic device includes coating a first layer of polyimide onto a carrier, curing the first layer of polyimide by subjecting the first layer of polyimide to an elevated temperature, depositing a first layer of metal onto the cured first layer of polyimide, coating a second layer of polyimide onto the first layer of metal, curing the second layer of polyimide by subjecting the second layer of polyimide to an elevated temperature, depositing a second layer of metal onto the cured second layer of polyimide, coating a third layer of polyimide onto the second layer of metal, curing the third layer of polyimide by subjecting the second layer of polyimide to an elevated temperature, depositing a dielectric barrier layer onto the third layer of polyimide, fabricating a thin film transistor-based device onto the dielectric barrier layer, and releasing the multi-layered polymer film from the carrier without the use of laser ablation.

The method for fabricating a multi-layered flexible electronic device include where the multi-layered flexible electronic device has little to no curl after release. The method for fabricating a multi-layered flexible electronic device includes where the first layer of metal is deposited in a pattern that does not cover an entire surface of the first layer of polyimide, and the second layer of metal is deposited in a pattern that does not cover an entire surface of the second layer of polyimide. The method for fabricating a multi-layered flexible electronic device includes where the first layer of polyimide, the second layer of polyimide, and the third layer of polyimide are each from about 10 microns to about 20 microns thick, and the first layer of metal and the second layer of metal are each from about 100 nanometers to about 200 nanometers thick.

A flexible electronic device is disclosed. The flexible electronic device includes a first layer of polyimide, a first layer of metal disposed on the first layer of polyimide, a second layer of polyimide disposed on the first layer of metal, a second layer of metal disposed on the second layer of polyimide, a third layer of polyimide disposed on the second layer of metal, a dielectric barrier layer disposed on the third layer of polyimide, and a thin film transistor-based device disposed on the dielectric barrier layer.

The flexible electronic device further includes where the first layer of polyimide, the second layer of polyimide, and the third layer of polyimide are each from about 10 microns to about 20 microns thick. The metal may include molybdenum. The first layer of metal and the second layer of metal are each from about 100 nanometers to about 200 nanometers thick. The dielectric barrier layer may include silicon nitride. The flexible electronic device has little to no curl.

### BRIEF DESCRIPTION OF THE DRAWINGS

The accompanying drawings, which are incorporated in and constitute a part of this specification, illustrate embodiments of the present teachings and together with the description, serve to explain the principles of the disclosure. In the figures:

FIGS. 1A-1B are cross-sectional schematic views of two embodiments of a flexible electronic device, in accordance with one or more embodiments.

FIGS. 2A-2B are data plots illustrating bow and warp, respectively as measured during steps of a fabrication process of a flexible electronic device, in accordance with one or more embodiments.

FIGS. 3A-3B are data plots illustrating peel strength, as measured during steps of a fabrication process of a flexible electronic device, in accordance with one or more embodiments.

FIGS. 4A-4B are data plots illustrating height measurements taken during steps of a fabrication process of a flexible electronic device, in accordance with one or more embodiments.

FIG. 5 is a flowchart illustrating a method for coating a multi-layered polymer film, in accordance with one or more embodiments.

FIG. 6 is a flowchart illustrating a method for fabricating a multi-layered flexible electronic device, in accordance with one or more embodiments.

It should be noted that some details of the figures have been simplified and are drawn to facilitate understanding of the present teachings rather than to maintain strict structural accuracy, detail, and scale.

### DETAILED DESCRIPTION

Reference will now be made in detail to exemplary embodiments of the present teachings, examples of which are illustrated in the accompanying drawings. Wherever possible, the same reference numbers will be used throughout the drawings to refer to the same, similar, or like parts.

Flexible polyimide substrates and accompanying processing techniques as applied to fabrication of flexible substrates for electronics and electronics products, for example, can result in internal mechanical stresses resulting in noticeable curl, which may render the polyimide quite difficult to handle.

Exemplary aspects of the present disclosure include methods to provide a thicker polyimide substrate thickness without a debilitating curl while maintaining mechanical release property without the use of external techniques, such as laser ablation. These methods and resulting devices or flexible, multi-layered films may be applied to a wide range of electronic devices such as flexible displays, digital x-ray detectors, interposers for 3D packaging, and medical devices. Flexible polyimide substrates for flexible electronics that can be removed from a carrier mechanically as opposed to additional methods provide an advantageous method of fabricating all or a portion of a flexible electronic device or film. Exemplary examples of resulting multi-layered films have an advantage of similar physical properties throughout process steps, as well as providing a more efficient process resulting in flatter, easier to handle flexible electronic substrates and devices.

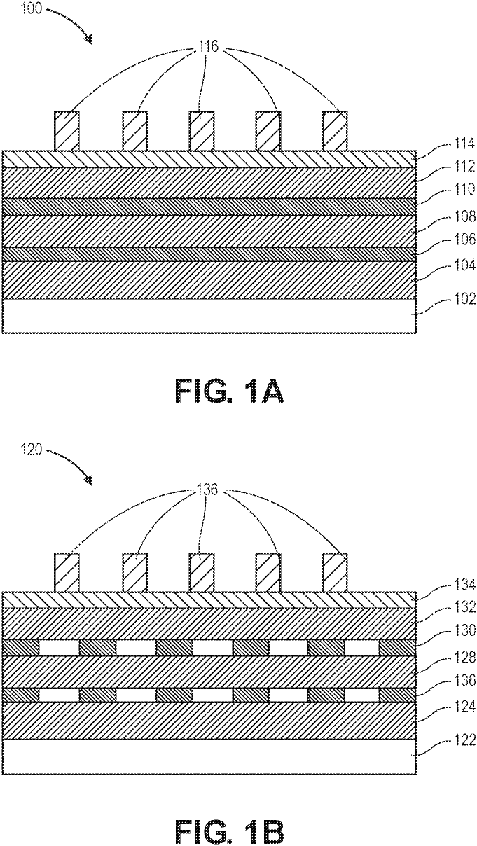

FIGS. 1A-1B are cross-sectional schematic views of two embodiments of a flexible electronic device, in accordance with one or more embodiments. FIG. 1A illustrates an exemplary example of a flexible electronic device 100 including a multi-layered film as described herein. A substrate or carrier 102 is used to hold and build the multi-layered film upon it and facilitate handling and processing during the fabrication steps. On the carrier 102 is a first layer of polyimide 104, followed by a first layer of metal 106 disposed on the first layer of polyimide 104. Upon the first layer of metal 106 is a second layer of polyimide 108 disposed on the first layer of metal 106, followed by a subsequent second layer of metal 110 disposed on the second layer of polyimide 108. Next is a third layer of polyimide 112 disposed on the second layer of metal 110. In certain embodiments, additional alternating or interstitial layers of metal and polyimide may be deposited upon one another to continue to build an overall multi-layered film. Upon the third layer of polyimide 112 a dielectric barrier layer 114 is disposed. Upon the dielectric barrier layer 114, one or more electronic device components 116, such as one or more thin film transistor (TFT) based device may be disposed.

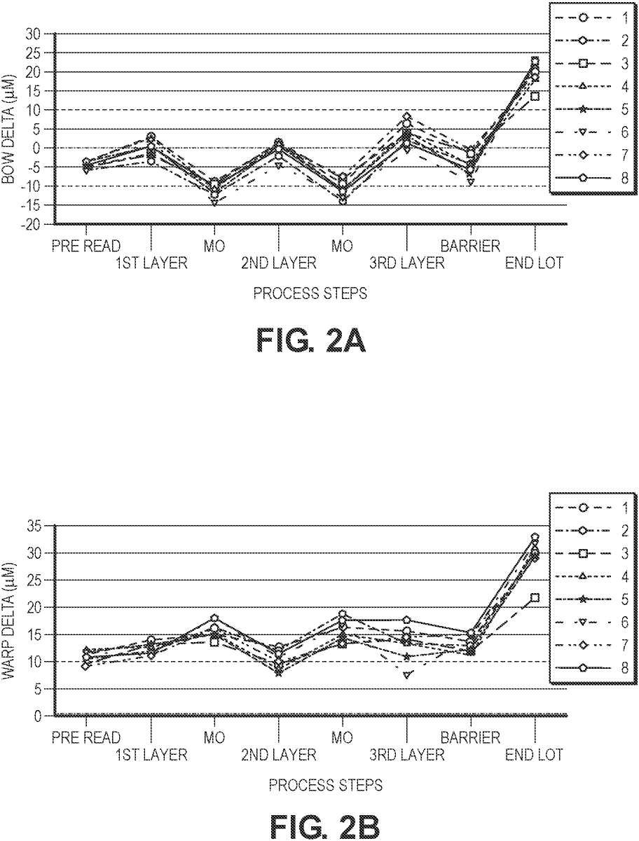

FIG. 1B illustrates an exemplary example of a flexible electronic device 120 including a multi-layered film as described herein. A substrate or carrier 122 is used to hold and build the multi-layered film upon it and facilitate handling and processing during the fabrication steps. On the carrier 122 is a first layer of polyimide 124, followed by a first layer of metal 126 disposed on the first layer of polyimide 124. Upon the first layer of metal 126 is a second layer of polyimide 128 disposed on the first layer of metal 126, followed by a subsequent second layer of metal 130 disposed on the second layer of polyimide 128. In the flexible electronic device 120 of FIG. 2B, the first layer of metal 126 or second layer of metal 130, as well as any subsequent layers of metal, are deposited in a pattern that does not cover an entire surface of the underlying layer of polyimide 124, 128. For example, the metal may be deposited in a grid-like pattern, a striped pattern, or a pattern that produces trenches or a circuit trace for a circuit path for a portion of a final flexible electronic device. One or more of the metal layers 126, 130 may also have electrical continuity between one or more additional metal layers in an alternate flexible electronic device having more than one metal layer. Next is a third layer of polyimide 132 disposed on the second layer of metal 130. In certain embodiments, additional alternating or interstitial layers of metal and polyimide may be deposited upon one another to continue to build an overall multi-layered film. Upon the third layer of polyimide 132 a dielectric barrier layer 134 is disposed. Upon the dielectric barrier layer 134, one or more electronic device components 136, such as one or more thin film transistor (TFT) based device may be disposed.

In alternate exemplary examples of the above flexible electronic devices or multi-layered films, alternate carrier materials may be used, such as a silicon material, while in other examples a glass carrier may be used. It should be noted that after fabrication, all layers above the carrier are removed from the carrier after fabrication, heating, or other processing steps. While the polyimide layers are spin coated, other polyimide coating methods may be used as well, including spray coating, flow coating, dip coating, slot die coating, extrusion coating, and the like. After curing, the layers of polyimide are each from about 10 microns to about 20 microns thick or from about 5 microns to about 40 microns, or from about 10 microns to about 30 microns thick. Suitable polyimide materials for use include HD Microsystems PI2611, Fujifilm Durimide 7510, and the like. Methods of deposition for the metal layers as described herein may include chemical or physical vapor deposition methods, such as Low-pressure chemical vapor deposition (LPCVD), Ultrahigh vacuum CVD (UHVCVD), Plasma-enhanced CVD (PECVD), and the like, or combinations thereof. In exemplary embodiments, the one or more metal layers are molybdenum, but in alternate embodiments the metal may be other refractory metals or metals that do not react with water, such as niobium, tantalum, tungsten and rhenium or alternatively titanium, vanadium, chromium, zirconium, hafnium, ruthenium, rhodium, osmium, iridium, or a combination of one or more of the metals described herein. Metal layer alternative materials wherein the metal comprises molybdenum. wherein the first layer of metal and the second layer of metal are each from about 100 nanometers to about 200 nanometers thick. The one or more metal layer thicknesses may be from about 50 nanometers to about 750 nanometers thick, or from about 75 nanometers to about 300 nanometers thick, or about 100 nanometers to about 200 nanometers thick. The dielectric barrier layer is silicon nitride, silicon dioxide, aluminum oxide, hafnium oxide, titanium nitride, tantalum nitride or other dielectric materials. The dielectric barrier layer may be deposited on top of a polyimide layer via plasma enhanced chemical vapor deposition (PECVD), atomic layer deposition (ALD), reactive sputtering, or evaporation at a thickness of from about 50 nm to about 800 nm.

When multi-layered films or flexible electronic device substrates are fabricated as described herein, additional solvents, temperature, special equipment, or processing steps are not required to remove the film or device from the carrier. Additional steps that are used in more conventional flexible electronics substrate process may include a dehydration bake, wherein certain high temperatures or high humidity in the processing steps may harm electronic substrates. Other means such as laser ablation are costly and may damage certain electronic components. Using the molybdenum or other metal layer provides an interstitial layer deposited via sputter deposition from an elemental target within the layers of polyimide in the flexible multi-layered film thereby providing a multi-layered polymer film, or a multi-layered flexible electronic device having little to no curl where curl can be defined as the radius of curvature of the flexible substrate at rest which can range from 400 mm to 100000 mm. Without the metal interlayers, the curl radius of curvature can be less than 10 mm. This measurement of curl is typically conducted by visual inspection, however, alternate measurement methods are known to those skilled in the art. While not wishing to be bound by any particular theory, the metal interstitial layer strengthens the overall flexible electronic substrate structure, affording a polyimide process that is manually de-bondable, resists curl, and results in a process that may eliminate dehydration bakes. However, as is usually the case, the adhesion strength between an initial layer of polyimide and the carrier may be sufficiently strong. The additional interstitial metal layers may add strength and reduce stretching and improve the physical properties, such as toughness, tensile strength, Young’s modulus, for example, of the multi-layered film during processing, thereby reducing handling and processing damage. Additionally, the one or more metal layers may act as a water vapor transmission barrier by providing an alternating organic/inorganic layer structure in the fabricated film or device, adding a tortuosity to the path that water must take through the bulk of the film. This is believed to be advantageous in preventing damage of humidity sensitive electronic components. Furthermore, the one or more metal layers may reduce or eliminate some of the mismatch of stresses when processing, in particular allowing reduced damage while the multi-layered film is being removed from the carrier. The PI can be peeled off. Certain exemplary examples may allow for a tunability of adhesion by using a metal layer as an initial layer deposited onto the carrier prior to an initial layer of polyimide.

FIGS. 2A-2B are data plots illustrating bow and warp, respectively as measured during steps of a fabrication process of a flexible electronic device, in accordance with one or more embodiments. FIG. 2A is a chart illustrating a bow delta, in microns, measured from the center of the carrier or wafer to the edge of the carrier or wafer, during the process steps of the fabrication of a flexible electronic device. The data demonstrates a more than adequate bow at the end of the process, as +/- 10 microns is an industry standard acceptable result. Some deflection is noted from center to fitted edge of the surface layer. Warp, as shown in FIG. 2B, illustrates a measurement of a relative peak to valley, or a lowest point to a highest point, during the various process steps of the fabrication of a flexible electronic device during the process steps of the fabrication of a flexible electronic device. FIG. 2B illustrates that the samples measured indicate a slight bowl-shaped result, but still within acceptable standards for semiconductor wafer processing equipment. Measurements are taken after each process step in the same locations each time with a total of five different locations on the wafer or carrier.

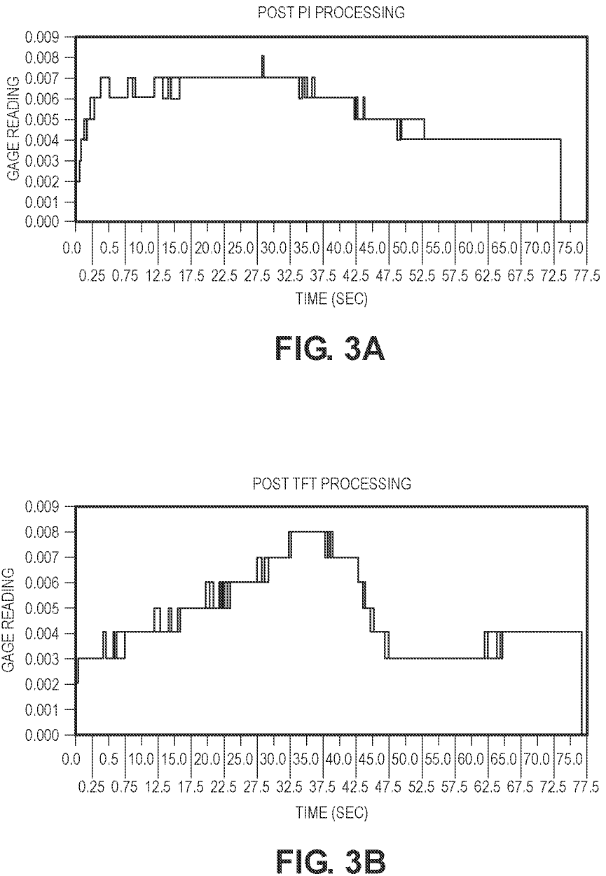

FIGS. 3A-3B are data plots illustrating peel strength, as measured during steps of a fabrication process of a flexible electronic device, in accordance with one or more embodiments. The peak peel strength over time in FIG. 3A for post polyimide processing is the same, at 0.0080 kg/in, as the peak peel strength results measured for post TFT processing, showing essentially no difference in PEEL strength pre and post TFT process. Further destructive testing on these samples also shows no delamination of polyimide layers.

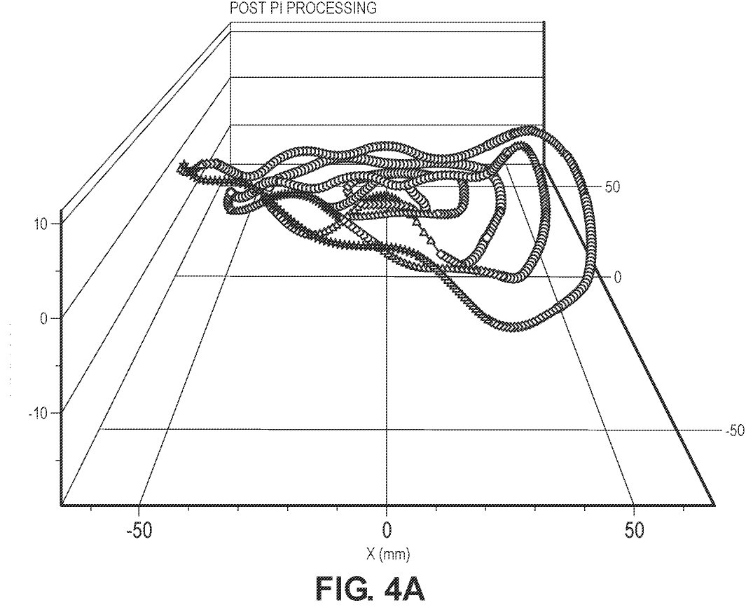

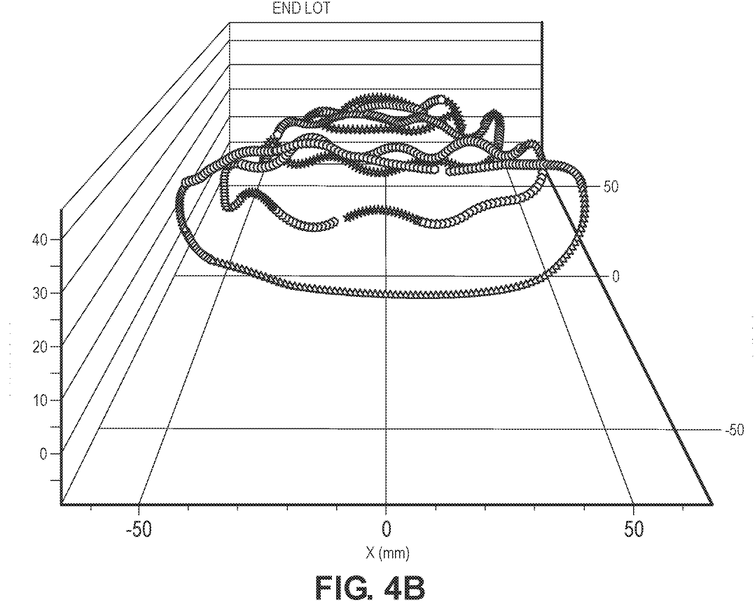

FIGS. 4A-4B are elevation relief maps showing the wafer shape and deflection taken during steps of a fabrication process of a flexible electronic device, in accordance with one or more embodiments. FIG. 4A is a plot illustrating height measurements of an exemplary example in accordance with one or more embodiments as disclosed herein after three layers of polyimide have been coated in a flexible electronic device substrate. The wafer does not demonstrate a pronounced bowl shape. FIG. 4B is a plot of the same substrate measured in FIG. 4B after the fabrication of one or more TFT-based components onto a silicon nitride dielectric barrier layer was deposited onto the polyimide surface. The “End Lot” data plot of FIG. 4B illustrates somewhat of a dome shaped result. While general characteristics of the shape of the flexible electronic device are shown, these measurements and magnitudes of shape characteristics shown in FIGS. 4A and 4B are still well within acceptable manufacturing standards for semiconductor processing equipment.

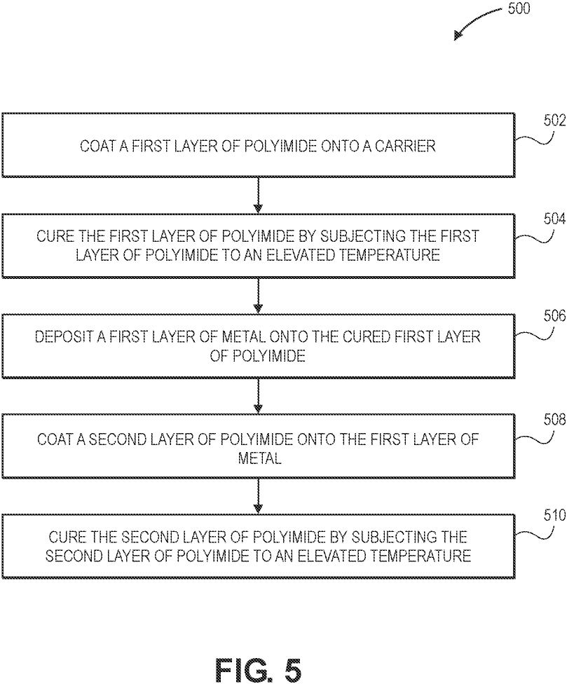

FIG. 5 is a flowchart illustrating a method for coating a multi-layered polymer film, in accordance with one or more embodiments. A method for coating a multi-layered polymer film 500, includes an initial step to coat a first layer of polyimide onto a carrier 502. The coating may be accomplished by one or more methods known to those skilled in the art. For example, spin coating may be done, using spin coating parameters of about 250 rpm to about 10,000 rpm, or from about 500 rpm to about 5,000 rpm, or from about 500 rpm to about 1000 rpm. The spin coating step may be conducted for about 10 seconds to about 120 seconds, or from about 15 seconds to about 60 seconds, or from about 20 seconds to about 30 seconds. The carrier, coating solution, or environment may be exposed to a specific temperature during the coating step. Other means of coating may be used for the polyimide layer, including spray coating, flow coating, dip coating, and the like. Alternative embodiments may include the application of an adhesive or alternatively, a release agent, to the carrier prior to the first layer of polyimide being coated onto the carrier. In certain embodiments the carrier is a silicon material, while in other examples a glass carrier may be used. A next step in the method for coating a multi-layered polymer film 500 is to cure the first layer of polyimide by subjecting the first layer of polyimide to an elevated temperature 504. During curing, the multi-layered polymer film, or the flexible electronic device is exposed to an inert atmosphere prior to curing, such as under a nitrogen, argon or otherwise inert atmosphere composition known to one skilled in the art. The elevated temperature used while exposing the film in an oven or with the use of an alternate heating method includes the use of a temperature of at least 340° C. for 1 hour. For example, the heating exposure may include from about 300° C. to about 400° C., or from about 325° C. to about 375° C., or from about 340° C. to about 360° C. The exposure time may be from about 30 minutes to about 120 minutes, or from about 45 minutes to about 90 minutes, or from about 50 minutes to about 75 minutes.

Next, a first layer of metal is deposited onto the cured first layer of polyimide 506. In exemplary embodiments, the metal may be molybdenum, but in alternate embodiments the metal may be other refractory metals or metals that do not react with water, such as niobium, tantalum, tungsten and rhenium or alternatively titanium, vanadium, chromium, zirconium, hafnium, ruthenium, rhodium, osmium, iridium, or a combination of one or more of the metals described herein. The next step in the method for coating a multi-layered polymer film 500 is to coat a second layer of polyimide onto the first layer of metal 508 under similar conditions and parameters as described previously, and finally to cure the second layer of polyimide by subjecting the second layer of polyimide to an elevated temperature 510. After curing, the first layer of polyimide and the second layer of polyimide are each from about 10 microns to about 20 microns thick or from about 5 microns to about 40 microns, or from about 10 microns to about 30 microns. The first metal layer thickness may be from about 50 nanometers to about 500 nanometers thick, or from about 75 nanometers to about 300 nanometers thick, or about 100 nanometers to about 200 nanometers thick. In certain embodiments, the first layer of metal may be deposited in a pattern that does not cover an entire surface of the first layer of polyimide. For example, the metal may be deposited in a grid-like pattern, a striped pattern, or a pattern that produces a circuit trace for a circuit path for a portion of a final flexible electronic device. The first metal layer may also have electrical continuity between one or more additional metal layers in an alternate flexible electronic device having more than one metal layer. Methods of deposition for a metal layer as described herein may include chemical or physical vapor deposition methods, such as Low-pressure CVD (LPCVD), Ultrahigh vacuum CVD (UHVCVD), Plasma-enhanced CVD (PECVD), and the like, or combinations thereof..

The method for coating a multi-layered polymer film 500 may further include releasing the multi-layered polymer film from the carrier without the use of laser ablation. The method for coating a multi-layered polymer film 500 may also include depositing a second layer of metal onto the cured second layer of polyimide, coating a third layer of polyimide onto the second layer of metal, and curing the third layer of polyimide by subjecting the third layer of polyimide to an elevated temperature. While three layers of polyimide are described in the method for coating a multi-layered polymer film 500, additional, alternating layers of polyimide and metal may be deposited, up to about 12 layers of polyimide, or more. In some embodiments of the method for coating a multi-layered polymer film 500 a dielectric barrier layer is deposited onto the second layer of polyimide, and a thin film transistor-based device may be fabricated onto the dielectric barrier layer. In such cases where more than two layers of polyimide are coated, the dielectric barrier and subsequent thin film transistor-based device would be deposited onto the final layer of coated polyimide. Alternative embodiments of the method for coating a multi-layered polymer film 500 may include other electronic components aside from thin film transistor-based components, such as any microelectronic device that could be made, for example, photocells, photodiodes, x-ray detectors, active matrix displays, medical devices, or structures with multiple thin film active layers, as long as processing below approximately 450° C. is possible.. The dielectric barrier layer may include silicon nitride, silicon dioxide, aluminum oxide, hafnium oxide, titanium nitride, tantalum nitride or other semiconductor material compositions. Exemplary embodiments of the method for coating a multi-layered polymer film 500 result in a multi-layered polymer film having little to no curl, as described herein, but in exemplary examples, having a radius of curvature above 500 mm.

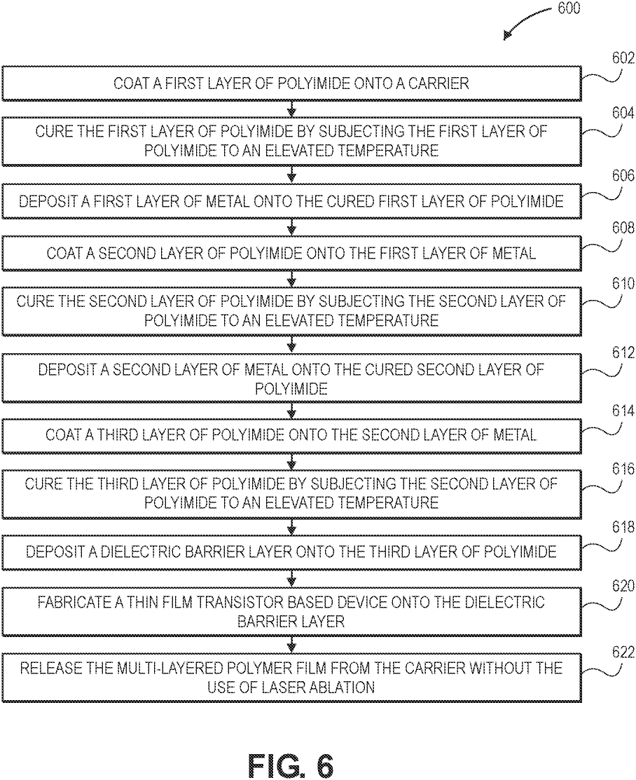

FIG. 6 is a flowchart illustrating a method for fabricating a multi-layered flexible electronic device, in accordance with one or more embodiments. A method for fabricating a multi-layered flexible electronic device 600 begins with a step to coat a first layer of polyimide onto a carrier 602, followed by a step to cure the first layer of polyimide by subjecting the first layer of polyimide to an elevated temperature 604. Next, a step to deposit a first layer of metal onto the cured first layer of polyimide 606 is completed. In some embodiments, the first layer of metal is deposited in a pattern that does not cover an entire surface of the first layer of polyimide, such as a grid-like pattern, a striped pattern, or a pattern that produces a circuit trace for a circuit path for a portion of a final flexible electronic device. The first metal layer, as well as any subsequent metal layers, may also have electrical continuity between one or more additional metal layers in an alternate flexible electronic device having more than one metal layer. Next, a second layer of polyimide is coated onto the first layer of metal 608, followed by curing the second layer of polyimide by subjecting the second layer of polyimide to an elevated temperature 610. A second layer of metal is deposited onto the cured second layer of polyimide 612. In certain embodiments, the second layer of metal is deposited in a pattern that does not cover an entire surface of the second layer of polyimide. Next a third layer of polyimide is coated onto the second layer of metal 614, followed by curing the third layer of polyimide by subjecting the second layer of polyimide to an elevated temperature 616. Finally, a dielectric barrier layer is deposited onto the third layer of polyimide 618, followed by fabricating a thin film transistor-based device onto the dielectric barrier layer 620, and releasing the multi-layered polymer film from the carrier without the use of laser ablation 622. In some embodiments for fabricating a multi-layered flexible electronic device 600, the layers of polyimide and the layers of metal have similar thicknesses as previously described. Furthermore, the resulting fabricated multi-layered flexible electronic device has little to no curl after de-bonding from the carrier.

### Experimental

In one or more exemplary embodiments in accordance with the flexible devices and/or flexible device substrates as described herein, a three-layer polyimide substrate was fabricated with 2 interstitial layers of molybdenum therein. In an initial step, adhesion promoter (VM652, available from HD Microsystems, is applied to a silicon carrier. The use of an adhesion promoter is to ensure that the polyimide will stay adhered to the edge of the wafer or carrier, and is optional. ‘s edge. Application of the adhesion promoter is conducted using a sponge tip and at the edge of the wafer, extending inward approximately 1 mm. The adhesion promoter can be dried at room temperature or elevated heat upwards to 130C. Next, a first 20-micron polyimide layer, U Varnish S (available from Ube Industries, Ltd.), is dispensed from a syringe and spin coated onto the carrier at 1000 rpm for 20 seconds at a constant temperature of 60° C. and held for 15 minutes. Then the carrier having the first layer of polyimide is placed in a convection oven set to 340° C. for 60 minutes. The flatness of the first polyimide layer surface is measured on a Tamar WaferScan. Next a 150 nm layer of molybdenum is sputter coated onto the surface of the first layer of polyimide. A second 20-micron polyimide layer is dispensed from a syringe and spin coated onto the carrier at 1000 rpm for 20 seconds at a constant temperature of 60° C. and held for 15 minutes. Then the carrier, first layer of polyimide, first molybdenum layer, and second layer of polyimide is placed in a convection oven set to 340° C. for 60 minutes. The flatness of the second polyimide layer surface is measured on a Tamar WaferScan. Next a 150 nm layer of molybdenum is sputter coated onto the surface of the second layer of polyimide. A third 20-micron polyimide layer coated similarly to the first two layers of polyimide, and the entire structure is placed in an oven set to 340° C. for 60 minutes. The flatness of the third polyimide layer surface is measured on a Tamar WaferScan.

A silicon nitride layer, of 300 nm was then deposited onto the third polyimide layer surface, via plasma enhanced chemical vapor deposition (PECVD) using silane, hydrogen, and ammonia as feed gases, with an AMAT P5000 The entire flexible structure was then baked for 5 minutes under vacuum inside the PECVD chamber and the flatness of the silicon nitride surface is then re-measured as before. The resulting flexible substrates were evaluated visually as well, resulting in a flat, multi-layered, easily de-bonded flexible substrate for electronic devices without visible curl. After the silicon nitride is deposited, a thin film transistor-based device can be fabricated on the substrate as if it were a silicon or glass wafer. Alternatives to silicon nitride may be useful, such as semi-conductor dielectrics, may also be used.

Additionally, substrates made in this manner were found to have no difference in peel strength after the polyimide coating process and any post-TFT process, where electronic components were fabricated onto a silicon nitride layer. Also, the peel strength is consistent throughout the coating process. Exemplary examples as described herein result in a substrate array that lays flat after de-bonding, a substrate that is able to be de-bonded without the use of a mechanical means, and as such, does not require laser ablation or other methods to de-bond. Additional advantages of substrates in accordance with the present disclosure show destructive testing shows no layer-to-layer delamination, and such flexible substrates offer a low-cost silicon interposer replacement for 3D packaging and flexible electronics. In some examples, the polyimide process adhesion strength may be tailored such that underlying patterned metals will adhere to the polyimide instead of the carrier wafer, thus eliminating the need to perform a through-silicon via etch in some flexible electronic architectures.

While the present teachings have been illustrated with respect to one or more implementations, alterations and/or modifications may be made to the illustrated examples without departing from the spirit and scope of the appended claims. For example, it may be appreciated that while the process is described as a series of acts or events, the present teachings are not limited by the ordering of such acts or events. Some acts may occur in different orders and/or concurrently with other acts or events apart from those described herein. Also, not all process stages may be required to implement a methodology in accordance with one or more aspects or embodiments of the present teachings. It may be appreciated that structural objects and/or processing stages may be added, or existing structural objects and/or processing stages may be removed or modified. Further, one or more of the acts depicted herein may be carried out in one or more separate acts and/or phases. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items may be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. The terms “couple,” “coupled,” “connect,” “connection,” “connected,” “in connection with,” and “connecting” refer to “in direct connection with” or “in connection with via one or more intermediate elements or members.” Finally, the terms “exemplary” or “illustrative” indicate the description is used as an example, rather than implying that it is an ideal. Other embodiments of the present teachings may be apparent to those skilled in the art from consideration of the specification and practice of the disclosure herein. It is intended that the specification and examples be considered as exemplary only, with a true scope and spirit of the present teachings being indicated by the following claims.

What is claimed is:

1. A method for coating a multi-layered polymer film, comprising:
coating a first layer of polyimide onto a carrier;
curing the first layer of polyimide by subjecting the first layer of polyimide to an elevated temperature;
depositing a first layer of metal onto the cured first layer of polyimide;
coating a second layer of polyimide onto the first layer of metal; and
curing the second layer of polyimide by subjecting the second layer of polyimide to an elevated temperature.

2. The method for coating a multi-layered polymer film of claim 1, further comprising releasing the multi-layered polymer film from the carrier without the use of laser ablation.

3. The method for coating a multi-layered polymer film of claim 2, wherein the multi-layered polymer film has little to no curl.

4. The method for coating a multi-layered polymer film of claim 1, further comprising:
depositing a second layer of metal onto the cured second layer of polyimide;
coating a third layer of polyimide onto the second layer of metal; and
curing the third layer of polyimide by subjecting the third layer of polyimide to an elevated temperature.

5. The method for coating a multi-layered polymer film of claim 1, wherein the carrier comprises silicon.

6. The method for coating a multi-layered polymer film of claim 1, wherein the carrier comprises glass.

7. The method for coating a multi-layered polymer film of claim 1, wherein the first layer of polyimide and the second layer of polyimide are each from about 10 microns to about 20 microns thick.

8. The method for coating a multi-layered polymer film of claim 1, wherein the metal comprises molybdenum.

9. The method for coating a multi-layered polymer film of claim 1, wherein the first layer of metal is from about 100 nanometers to about 200 nanometers thick.

10. The method for coating a multi-layered polymer film of claim 1, further comprising:
depositing a dielectric barrier layer onto the second layer of polyimide; and
fabricating a thin film transistor-based device onto the dielectric barrier layer.

11. The method for coating a multi-layered polymer film of claim 10, wherein the dielectric barrier layer comprises silicon nitride.

12. The method for coating a multi-layered polymer film of claim 1, further comprising exposing the first layer of polyimide to an inert atmosphere prior to curing; and wherein subjecting the first layer of polyimide to an elevated temperature further comprises a temperature of at least 340° C. for 1 hour.

13. The method for coating a multi-layered polymer film of claim 1, wherein the first layer of metal is deposited in a pattern that does not cover an entire surface of the first layer of polyimide.

14. A method for fabricating a multi-layered flexible electronic device, comprising:
coating a first layer of polyimide onto a carrier;
curing the first layer of polyimide by subjecting the first layer of polyimide to an elevated temperature;
depositing a first layer of metal onto the cured first layer of polyimide;
coating a second layer of polyimide onto the first layer of metal;
curing the second layer of polyimide by subjecting the second layer of polyimide to an elevated temperature;
depositing a second layer of metal onto the cured second layer of polyimide;
coating a third layer of polyimide onto the second layer of metal;
curing the third layer of polyimide by subjecting the second layer of polyimide to an elevated temperature;
depositing a dielectric barrier layer onto the third layer of polyimide;
fabricating a thin film transistor-based device onto the dielectric barrier layer; and
releasing the multi-layered flexible electronic device from the carrier without the use of laser ablation.

15. The method for fabricating a multi-layered flexible electronic device of claim 14, wherein the multi-layered flexible electronic device has little to no curl after release.

16. The method for fabricating a multi-layered flexible electronic device of claim 14, wherein:
the first layer of metal is deposited in a pattern that does not cover an entire surface of the first layer of polyimide; and
the second layer of metal is deposited in a pattern that does not cover an entire surface of the second layer of polyimide.

17. The method for fabricating a multi-layered flexible electronic device of claim 14, wherein:
the first layer of polyimide, the second layer of polyimide, and the third layer of polyimide are each from about 10 microns to about 20 microns thick; and
the first layer of metal and the second layer of metal are each from about 100 nanometers to about 200 nanometers thick.

18. A flexible electronic device, comprising:
a first layer of polyimide;
a first layer of metal disposed on the first layer of polyimide;
a second layer of polyimide disposed on the first layer of metal;
a second layer of metal disposed on the second layer of polyimide;
a third layer of polyimide disposed on the second layer of metal;
a dielectric barrier layer disposed on the third layer of polyimide; and
a thin film transistor-based device disposed on the dielectric barrier layer.

19. The flexible electronic device of claim 18, wherein the first layer of polyimide, the second layer of polyimide, and the third layer of polyimide are each from about 10 microns to about 20 microns thick.

20. The flexible electronic device of claim 18, wherein the metal comprises molybdenum.

21. The flexible electronic device of claim 18, wherein the first layer of metal and the second layer of metal are each from about 100 nanometers to about 200 nanometers thick.

22. The flexible electronic device of claim 18, wherein the dielectric barrier layer comprises silicon nitride.

23. The flexible electronic device of claim 18, wherein the flexible electronic device has little to no curl.
